(19) United States
(12) Patent Application Publication
(10) Pub. No.: US 2017/0254939 A1
(43) Pub. Date: Sep. 7, 2017

(54) METHOD FOR MANUFACTURING POLARIZING PLATE AND POLARIZING PLATE MANUFACTURED USING SAME

(71) Applicant: LG CHEM, LTD., Seoul (KR)

(72) Inventors: Byung Sun LEE, Daejeon (KR); Hyung Koo KANG, Daejeon (KR); Ho Jeong YUN, Daejeon (KR); Eung Jin JANG, Daejeon (KR); Kyun II RAH, Daejeon (KR)

(21) Appl. No.: 15/501,083

(22) PCT Filed: Oct. 5, 2015
(86) PCT No.: PCT/KR2015/010501

§ 371 Date: Feb. 1, 2017

(30) Foreign Application Priority Data
Oct. 6, 2014 (KR) 10-2014-0134101

(51) Int. Cl. G02B 5/30; C08K 3/16; G03F 7/00; G03F 7/039; G02F 1/1335; G03F 7/16; G03F 7/20; G03F 7/32; G02B 1/14; C08J 5/18; G03F 7/038

(52) U.S. Cl. CPC G02B 5/305; C08J 5/18; C08K 3/16; G03F 7/0005; G03F 7/039; G03F 7/038; G03F 7/16; G03F 7/168; G03F 7/2006; G03F 7/2004; G03F 7/322; G02B 1/14; G02F 1/133533; C08J 2329/04

(57) ABSTRACT

The present specification relates to a method for manufacturing a polarizing plate and a polarizing plate manufactured using the same. More specifically, the present specification relates to a method for manufacturing a polarizing plate which locally has a depolarized area and a polarizing plate manufactured using the same.

### TECHNICAL FIELD

This application claims priority to and the benefit of Korean Patent Application No. 10-2014-0134101 filed in the Korean Intellectual Property Office on Oct. 6, 2014, the entire contents of which are incorporated herein by reference.

The present invention relates to a method for manufacturing a polarizing plate and a polarizing plate manufactured using the same.

### BACKGROUND ART

A liquid crystal display is a display configured to visualize polarization caused by a switching effect of liquid crystal, and has been used in various categories including small and medium displays such as a wrist watch, an electronic calculator, a mobile phone, and a large-screen TV.

Recently, small and medium display devices or notebook computers of which portability and mobility are emphasized have become commonly equipped with various functions such as camera and video communication, and liquid crystal displays recently released to perform the above-described functions has a structure in which a camera lens is exposed to the outside.

However, a liquid crystal display device should include a polarizer or a polarizing plate attached to an outer surface of a liquid crystal cell. While being attached, the polarizer or polarizing plate may cover the camera lens exposed to the outside, so that visibility of the lens may be decreased due to the polarizing plate's intrinsic transmittance of lower than 50%.

In order to solve this problem, when the polarizing plate is attached, a physical removal method of perforating and removing a part of the polarizing plate covering the camera lens by punching or cutting and/or a chemical removal method of detaching or bleaching a part of the polarizing plate covering the camera lens with a chemical material of iodine ions has been used. However, such a method has disadvantages of damage to the lens, contamination of the lens, and difficulty in precisely controlling an area to be removed.

Accordingly, a method for manufacturing a polarizing plate to be applied to a display device having a structure in which a camera lens is exposed to the outside needs to be researched.

### DETAILED DESCRIPTION OF THE INVENTION

### Technical Problem

The present specification provides a method for manufacturing a polarizing plate and a polarizing plate manufactured using the same.

### Technical Solution

An aspect of the present specification provides a method for manufacturing a polarizing plate, including:

providing a polyvinyl alcohol-based polarizer dyed with at least one of iodine and a dichroic dye;
providing a protective film on one surface of the polarizer;

providing a mask layer including at least one perforation part on the other surface of the polarizer; and

forming a depolarized area having a single transmittance of 80% or more in a wavelength band of 400 nm to 800 nm by bringing a bleaching solution including 1 wt % to 30 wt % of a bleaching agent into local contact with the other surface of the polarizer on which the mask layer is provided,

wherein a surface tension of the bleaching solution is 50 mN/m or less.

Further, another aspect of the present specification provides a polarizing plate manufactured by the above-described manufacturing method.

Furthermore, yet another aspect of the present specification provides an image display device, including:

a display panel; and

the polarizing plate attached to one surface or both surfaces of the display panel.

Moreover, still another aspect of the present specification provides a bleaching solution having a surface tension of 50 mN/m or less.

### Advantageous Effects

In the method for manufacturing a polarizing plate according to an aspect of the present specification, a bleached area is formed at a desired position through a chemical bleaching method without performing a punching or cutting process. Thus, damage to the polarizing plate can be minimized. Further, the method for manufacturing a polarizing plate according to an aspect of the present specification includes consecutive processes and thus has an excellent process efficiency and requires low manufacturing costs.

Further, in the method for manufacturing a polarizing plate according to an aspect of the present specification, generation of a micro bubble during a bleaching process is suppressed. Thus, while the consecutive processes are performed, a defect rate can be reduced, resulting in stabilization in performing the consecutive processes.

Furthermore, the polarizing plate manufactured by the method for manufacturing a polarizing plate according to an aspect of the present specification includes an almost transparent depolarized area in a portion where components are mounted or an area where a color is developed. Thus, it is possible to suppress deterioration in performance of components to be mounted and also possible to implement various colors and/or designs.

### BRIEF DESCRIPTION OF DRAWINGS

FIG. 1 is a flowchart provided to explain a method for manufacturing a polarizing plate according to an exemplary embodiment of the present specification.

FIG. 2 is a diagram provided to explain a reason for generation of a micro bubble that causes generation of an unbleached site while a depolarized area is formed.

FIG. 3 is a diagram illustrating an unbleached site caused by a micro bubble.

FIG. 4 is a diagram provided to explain a reason for non-generation of an unbleached site in Examples 1 to 3.

### BEST MODE

Hereinafter, the present specification will be described in more detail.

As for a conventional polarizing plate, the entire area of the polarizing plate is dyed with iodine and/or a dichroic dye, so the polarizing plate has dark black color. Therefore, it is difficult to give various colors to a display device. Particularly, if the polarizing plate is positioned on a component such as a camera, the polarizing plate absorbs 50% or more of the amount of light, so that visibility of the camera lens is decreased.

In order to solve this problem, a method of punching a hole (perforation) in a part of the polarizing plate by punching, cutting, or the like, to physically remove the part of the polarizing plate covering the camera lens has been used.

However, the physical method degrades the appearance of an image display device and may damage the polarizing plate due to the nature of a hole-punching process. Meanwhile, in order to suppress damage such as tearing of the polarizing plate, a perforation part of the polarizing plate needs to be formed sufficiently apart from an edge. Therefore, if the polarizing plate is applied to the image display device, a bezel unit of the image display device becomes relatively wide, which leads to a problem of being out of a recent narrow bezel design trend for realizing a large screen of an image display device. In addition, if a camera module is installed on a perforation part of the polarizing plate as described above, a camera lens is exposed to the outside, which may cause a problem of contamination and damage to the camera lens when used for a long period of time.

Accordingly, the present disclosure provides a chemical method that enables polarization to be removed by a simple process without physically punching a hole and degrading the appearance. Specifically, the present specification provides a chemical method with excellent ease of performing consecutive processes and stability in the consecutive processes.

An exemplary embodiment of the present specification provides a method for manufacturing a polarizing plate, including: providing a polyvinyl alcohol-based polarizer dyed with at least one of iodine and a dichroic dye; providing a protective film on one surface of the polarizer; providing a mask layer including at least one perforation part on the other surface of the polarizer; and forming a depolarized area having a single transmittance of 80% or more in a wavelength band of 400 nm to 800 nm by bringing a bleaching solution including 1 wt % to 30 wt % of a bleaching agent into local contact with the other surface of the polarizer on which the mask layer is provided, wherein a surface tension of the bleaching solution is 50 mN/m or less.

Herein, the other surface of the polarizer refers to an opposite surface on which the protective film is not provided.

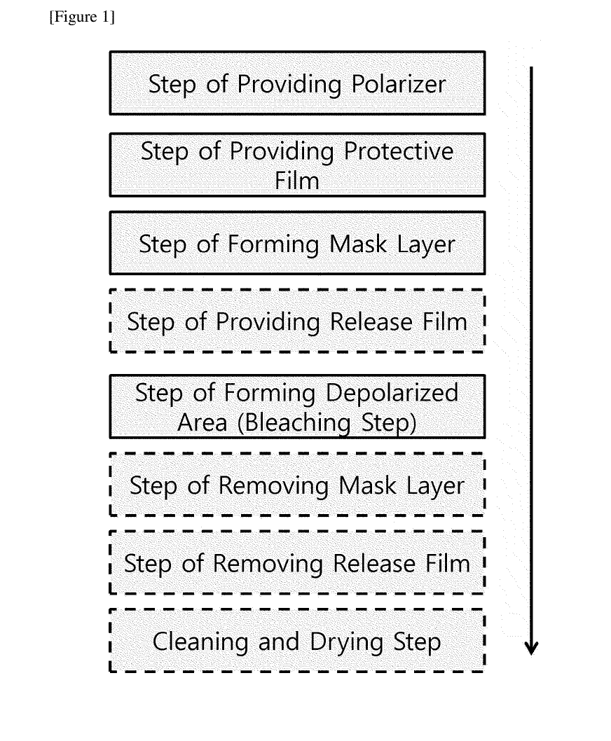

FIG. 1 illustrates a schematic flowchart of a method for manufacturing a polarizing plate according to an exemplary embodiment of the present specification.

As illustrated in FIG. 1, the method for manufacturing a polarizing plate according to an exemplary embodiment of the present specification includes: providing a polyvinyl alcohol-based polarizer dyed with at least one of iodine and a dichroic dye; providing a protective film on one surface of the polarizer; providing a mask layer including at least one perforation part on the other surface of the polarizer; and forming a depolarized area by bringing a bleaching solution into contact with the other surface of the polarizer on which the mask layer is provided.

Meanwhile, the method for manufacturing a polarizing plate according to an exemplary embodiment of the present specification may further include a step of providing a release film, a step of removing the mask layer, a step of removing the release film, and/or a cleaning step according to necessity.

In the present specification, the term “providing” may mean “laminating”.

The inventors of the present invention found that if a depolarized area is locally formed by selectively bringing a bleaching solution into contact with a part of a polyvinyl alcohol-based polarizer dyed with iodine and/or a dichroic dye, a perforation is not generated unlike a physical method such as punching and cutting, and a bleaching process is performed after a protective film is laminated on one surface of the polarizer, so that swelling of the polarizer is suppressed and micro wrinkles in a depolarized area can be minimized

In general, if a bleaching solution is brought into direct contact with a polyvinyl alcohol-based polarizer on which a protective film is not laminated, the polarizer is swollen due to moisture, so that wrinkles may be formed in a depolarized area and around the depolarized area. In this case, a surface roughness of the depolarized area is increased and haze is increased. Accordingly, it is difficult to sufficiently obtain the appearance of a polarizing plate and the visibility of a camera positioned in the depolarized area. In this regard, if a protective film is laminated on one surface of a polarizer before a contact with a bleaching solution according to the method for manufacturing a polarizing plate of the present specification, the protective film and the polarizer are bonded to each other, so that swelling and wrinkles can be suppressed.

Further, the inventors of the present invention found that it is possible to efficiently improve the ease of consecutive processes and the suppression of defects by using a bleaching solution having a low surface tension, specifically 50 mN/m or less and providing a mask layer including one or more perforation parts before bringing a polarizer into contact with the bleaching solution and then forming a depolarized area.

Hereinafter, each step of the method for manufacturing a polarizing plate according to an exemplary embodiment of the present specification will be described in more detail.

The polyvinyl alcohol-based polarizer may be manufactured by a method for manufacturing a PVA polarizer known in the art or may be used by purchasing a commercially available polyvinyl alcohol-based polarizer.

The step of providing a polyvinyl alcohol-based polarizer may be performed by, for example, but not limited to, dyeing a polyvinyl alcohol-based polymer film with iodine and/or a dichroic dye, crosslinking the polyvinyl alcohol-based film and the dye, and stretching the polyvinyl alcohol-based film.

Firstly, the dyeing step is performed to dye the polyvinyl alcohol-based film with iodine molecules and/or a dichroic dye. The iodine molecules and/or dichroic dye molecules absorb a light vibrating in an stretching direction of the polarizer and transmit a light vibrating in a vertical direction and thus make it possible to obtain polarization in a specific vibration direction. Herein, for example, the dyeing step may be performed by immersing the polyvinyl alcohol-based film in a processing bath filled with an iodine solution and/or a dichroic dye-containing solution.

Herein, water is typically used as a solvent in the solution used for the dyeing step, and a suitable amount of an organic solvent compatible with water may be added. Meanwhile, the iodine and/or the dichroic dye may be used in an amount of 0.06 parts by weight to 0.25 parts by weight with respect to 100 parts by weight of the solvent. If the dichroic material such as iodine is within the above-described range, the transmittance of the polarizer manufactured after stretching may satisfy the range of 40.0% to 47.0%.

Meanwhile, if iodine is used as the dichroic material, preferably, an adjuvant such as an iodide compound may be further included in order to improve the dyeing efficiency. The adjuvant may be used in an amount of 0.3 parts by weight to 2.5 parts by weight with respect to 100 parts by weight of the solvent. The reason for the use of the adjuvant such as an iodide compound is to increase the solubility of iodine in water since iodine has a low solubility in water. Meanwhile, preferably, the iodine and the iodide compound may have a weight mixing ratio of 1:5 to 1:10.

Specific examples of the iodide compound which can be added may include potassium iodide, lithium iodide, zinc iodide, aluminum iodide, lead iodide, copper iodide, valium iodide, calcium iodide, tin iodide, titanium iodide, or a mixture thereof, but are not limited thereto.

Meanwhile, a temperature of the processing bath may be maintained at 25° C. to 40° C. If the temperature of the processing bath is lower than 25° C., the dyeing efficiency may be decreased, and if the temperature of the processing bath is higher than 40° C., sublimation of a great amount of iodine occurs and the amount of iodine used may be increased.

Herein, preferably, a time of immersing the polyvinyl alcohol-based film in the processing bath may be 30 seconds to 120 seconds. If the immersion time is less than 30 seconds, uniform dyeing of the polyvinyl alcohol-based film may not be achieved, and if the immersion time is more than 120 seconds, dyeing may be saturated and thus the film does not need to be immersed any longer.

Meanwhile, the crosslinking step is performed to adsorb the iodine and/or the dichroic dye to a polyvinyl alcohol polymer matrix. The crosslinking step is generally performed using an immersion method in which the polyvinyl alcohol-based film is immersed in a crosslinking bath filled with an aqueous boric acid solution or the like, but is not limited thereto. It may also be performed by an application or spray method in which a solution including a crosslinking agent is applied or sprayed onto the polyvinyl alcohol-based film.

Herein, water is generally used as a solvent in the solution in the crosslinking bath, and a suitable amount of an organic solvent compatible with water may be added. The crosslinking agent may be added in an amount of 0.5 parts by weight to 5.0 parts by weight with respect to 100 parts by weight of the solvent. If the crosslinking agent is added in an amount of less than 0.5 parts by weight, the degree of crosslinking in the polyvinyl alcohol-based film may be insufficient, and, thus, the strength of the polyvinyl alcohol-based film in water may be reduced. If the crosslinking agent is added in an amount of more than 5.0 parts by weight, excessive crosslinking may occur, resulting in a decrease in the stretchability of the polyvinyl alcohol-based film. Further, specific examples of the crosslinking agent may include boron compounds such as boric acid or borax, glyoxal, glutaraldehyde and the like, which may be used alone or in combination. However, the present invention is not limited thereto.

Meanwhile, a temperature of the crosslinking bath varies depending on the amount of the crosslinking agent and the stretching ratio of the film, and is preferably between 45° C. and 60° C., but is not limited thereto. In general, as the amount of the crosslinking agent increases, the temperature of the crosslinking bath is controlled to a high temperature in order to increase the mobility of chains in the polyvinyl alcohol-based film, and as the amount of the crosslinking agent decreases, the temperature of the crosslinking bath is controlled to a relatively low temperature. However, according to the method for manufacturing a polarizing plate according to an exemplary embodiment of the present specification, the film is at least 5-fold stretched. Therefore, the temperature of the crosslinking bath needs to be maintained at 45° C. or higher in order to increase the stretchability of the polyvinyl alcohol-based film. Meanwhile, the time of immersing the polyvinyl alcohol-based film in the crosslinking bath may be preferably 30 seconds to 120 seconds. If the immersion time is less than 30 seconds, uniform crosslinking of the polyvinyl alcohol-based film may not be achieved, and if the immersion time is more than 120 seconds, crosslinking may be saturated and thus the film does not need to be immersed any longer.

Meanwhile, the stretching step is performed to align polymer chains in the polyvinyl alcohol-based film in a predetermined direction. Stretching methods can be classified into wet stretching methods and dry stretching methods. The dry stretching methods are further classified into an inter-roll stretching method, a heating roll stretching method, a press stretching method, a tenter stretching method, and the like, and the wet stretching methods are further classified into a tenter stretching method, an inter-roll stretching method, and the like.

Herein, the stretching step may be performed to stretch the polyvinyl alcohol-based film at a stretching ratio of preferably 4 times to 10 times. In order to impart polarizing performance to the polyvinyl alcohol-based film, polymer chains in the polyvinyl alcohol-based film need to be aligned. At a stretching ratio of less than 4 times, chains in the polyvinyl alcohol-based film may not be sufficiently aligned, and at a stretching ratio of more than 10 times, chains in the polyvinyl alcohol-based film may be cleaved.

Herein, the stretching step may be performed at a stretching temperature of preferably 45° C. to 60° C. The stretching temperature may vary depending on the amount of the crosslinking agent. At a temperature of less than 45° C., the mobility of chains in the polyvinyl alcohol-based film may be reduced and the stretching efficiency may be decreased, and at a temperature of more than 60° C., the polyvinyl alcohol-based film may become soft and thus may be decreased in strength. Meanwhile, the stretching step may be performed simultaneously with or separately from the dyeing step or the crosslinking step.

Meanwhile, the stretching step may be performed only to the polyvinyl alcohol-based film or may be performed to the polyvinyl alcohol-based film together with a base film after laminating the base film on the polyvinyl alcohol-based film. If the polyvinyl alcohol-based film having a small thickness (for example, a PVA film of 60 μm or less) is stretched, the base film is used to suppress breakage of the polyvinyl alcohol-based film during the stretching step and thus may be used to manufacture a thin PVA polarizer of 10 μm or less.

In this case, polymer films having the maximum stretching magnification of 5 times or more under a temperature of 20° C. to 85° C. may be used as the base film. For example, the base film may include a high-density polyethylene film, a polyurethane film, a polypropylene film, a polyolefin film, an ester-based film, a low-density polyethylene film, a co-extruded film of high-density polyethylene and low-density polyethylene, a copolymer resin film having ethylene vinyl acetate included in high-density polyethylene, an acrylic film, a polyethylene terephthalate film, a polyvinyl alcohol-based film, and a cellulose-based film. Meanwhile, the maximum stretching magnification indicates a stretching magnification immediately before the occurrence of breakage.

Further, a method of laminating the base film and the polyvinyl alcohol-based film is not particularly limited. For example, the base film and the polyvinyl alcohol-based film may be laminated using an adhesive, or the polyvinyl alcohol-based film may be placed on the base film without any medium. Otherwise, the method of laminating the base film and the polyvinyl alcohol-based film may be performed by co-extruding a resin constituting the base film and a resin constituting the polyvinyl alcohol-based film, or may be performed by coating a polyvinyl alcohol-based resin on the base film.

Meanwhile, after the stretching step is completed, the base film may be separated and removed from the polarizer or may not be removed and a subsequent step may be performed. In this case, the base film may be used as a protective film for the polarizer.

Then, if the polyvinyl alcohol-based polarizer is prepared by the above-described method, a step of providing a protective film on one surface of the polyvinyl alcohol-based polarizer may be performed.

The term “protective film” refers to a transparent film that is attached to one surface of the polarizer in order to protect the polarizer having a very small thickness. A film having excellent mechanical strength, thermal stability, moisture shielding property and isotropism may be used as the protective film. The protective film may be an acetate-based resin film such as a triacetyl cellulose (TAC) film, a polyester-based resin film, a polyethersulfone-based resin film, a polycarbonate-based resin film, a polyamide-based resin film, a polyimide-based resin film, a polyolefin-based resin film, a cycloolefin-based resin film, a polyurethane-based resin film, and an acryl-based resin film, but is not limited thereto.

Further, the protective film may be an isotropic film or may be an anisotropic film to which a compensation function such as retardation is provided, and the protective film may be configured as one film or may be configured by attaching two films or more. Further, the protective film may be a non-stretched film or a uniaxially or biaxially stretched film, and a thickness of the protective film may be generally 1 μm to 500 μm and preferably 1 μm to 300 μm.

In this case, adhesion force of the protective film to the polyvinyl alcohol-based polarizer may be preferably 1 N/2 cm or more and more preferably 2N/2 cm or more. Specifically, the adhesion force means adhesion force measured by 90° stripping force by using a texture analyzer after the protective film is attached onto the polyvinyl alcohol-based polarizer dyed with at least one of the iodine and the dichroic dye. If the adhesion force satisfies the above-described range, swelling of the protective film and the polyvinyl alcohol-based polarizer may be suppressed, and in a manufacturing process, the occurrence of curls and defects may be minimized

Meanwhile, the step of laminating the protective film on one surface of the polyvinyl alcohol-based polarizer is performed to attach the protective film onto the polarizer, and the protective film may be attached using an adhesive. In this case, the attachment may be performed through a lamination method of films known in the art, and for example, the attachment may be performed using an adhesive known in the art, such as a water-based adhesive such as a polyvinyl alcohol-based adhesive, a thermosetting adhesive such as a urethane-based adhesive, a light cation curable adhesive such as an epoxy-based adhesive, and a light radical curable adhesive such as an acryl-based adhesive.

Then, a step of providing a mask layer including at least one perforation part on the other surface of the polarizer on which the protective film is provided may be performed.

According to an exemplary embodiment of the present specification, the method may further include a step of forming a mask layer including at least one perforation part on the other surface of the polarizer before the step of forming the depolarized area. In this case, the mask layer may be formed of a mask film or a coating layer.

If the step of forming the mask layer is performed before the step of forming the depolarized area, there are merits in that a defect rate in a roll-to-roll process may be reduced since a portion not requiring depolarization, i.e., a portion not requiring bleaching is not covered by the mask layer, and a process speed is not limited since the polyvinyl alcohol-based polarizer and the mask layer are laminated.

According to an exemplary embodiment of the present specification, the step of forming the mask layer may be performed before the step of providing the protective film. If the polarizer on which the mask layer including the perforation part is formed is immersed in the bleaching solution, the bleaching solution comes into contact with the polyvinyl alcohol-based polarizer through the perforation part, and as a result, bleaching partially occurs only in a part corresponding to a perforation part region.

According to another exemplary embodiment, if the mask film is used as the mask layer, the step of forming the mask layer may include: forming the perforation part in the mask film; and attaching the mask film onto the other surface of the polarizer.

In this case, the mask film may be an olefin-based film such as polyethylene (PE), polypropylene (PP), and polyethylene terephthalate (PET); or a vinyl acetate-based film such as ethylene vinyl acetate (EVA) and polyvinyl acetate, but is not limited thereto. Further, a thickness of the mask film may be about 10 μm to about 100 μm and preferably about 10 μm to about 70 μm, but is not limited thereto.

The step of forming the perforation part in the mask film is not particularly limited, and may be performed by film perforating methods well known in the art, for example, die processing, knife processing, laser processing, and the like.

According to an exemplary embodiment of the present specification, the step of forming the perforation part may be performed by laser processing. The laser processing may be performed using laser processing devices generally known in the art, but is not particularly limited. Laser processing conditions such as the kind, power, and a laser pulse repetition rate of the laser device may be changed according to a material or a thickness of the film, a shape of the perforation part, and the like, and a person having ordinary skill in the art may appropriately select the laser processing conditions in consideration of the aforementioned matters. For example, in case of using the polyolefin film having a thickness of 30 μm to 100 μm as the mask film, the perforation part may be formed using a carbon dioxide (CO₂) laser device having a central wavelength of about 9 μm to about 11 μm, a UV device having a central wavelength of about 300 nm to about 400 nm, or the like. In this case, the maximum average power of the laser device may be about 0.1 W to about 30 W and the pulse repetition rate thereof may be about 0 kHz to about 50 kHz, but the laser device is not limited thereto.

The step of forming the perforation part may be performed before or after the step of attaching the mask film onto the other surface of the polarizer. In other words, the perforation part may be previously formed in the mask film and the mask film where the perforation part is formed may be then attached onto the polarizer, or the mask film may be attached onto the polarizer and the perforation part may be then formed.

The step of attaching the mask film onto the other surface of the polarizer may be performed by film lamination methods well known in the art, for example, a method for attaching the mask film and a polarizing member through an adhesive layer. In this case, the adhesive layer may be formed by applying an adhesive agent, such as an acryl-based adhesive agent, a silicon-based adhesive agent, an epoxy-based adhesive agent, and a rubber-based adhesive agent, on the mask film or the polarizing member, but the present invention is not limited thereto. For example, in case of using films having self-adhesive force (for example, EVA film, PVAC film, PP film, and the like) as the mask film, the mask film may be directly attached onto the other surface of the polarizer without forming the adhesive layer.

According to an exemplary embodiment of the present specification, if the mask layer is formed of the coating layer, the step of forming the mask layer includes: forming the coating layer on the other surface of the polarizer; and forming the perforation part by selectively removing a partial area of the coating layer.

The step of forming the coating layer may be performed by applying and drying a composition for forming the coating layer on the other surface of the polarizer or irradiating heat or an active energy beam such as a UV beam or an electron beam to cure the coating layer.

The kind of the composition for forming the coating layer is not particularly limited as long as the composition may be etched by a laser and is not dissolved in an alkaline solution. For example, as the composition for forming the coating layer, a composition including a dispersible polymer resin such as water-dispersible polyurethane, water-dispersible polyester, and a water-dispersible acryl copolymer, or a photosensitive resin composition may be used. Meanwhile, as the photosensitive resin composition, photosensitive resin compositions that are available on the market, for example, a positive type photoresist, a negative type photoresist, or the like may be used without particular limitation.

According to an exemplary embodiment of the present specification, the coating layer may be formed using a polymer resin composition or a photosensitive resin composition.

A method for applying the composition for forming the coating layer is not particularly limited, and the application may be performed by an application method generally used in the art, for example, bar coating, spin coating, roll coating, knife coating, spray coating, or the like, and the curing may be performed by a method for applying heat or irradiating the active energy beam, such as the UV beam or the electron beam, on the applied resin composition.

According to an exemplary embodiment of the present specification, a thickness of the coating layer may be 100 nm to 500 nm. If the thickness of the coating layer satisfies the above-described numerical range, there are merits in that when the perforation part is formed, it is possible to suppress damage to the polyvinyl alcohol-based polarizer and it is not necessary to additionally perform a process of removing the coating layer after the bleaching process.

The step of forming the perforation part by selectively removing a partial area of the coating layer may be performed by a method for irradiating the energy beam on the partial area of the coating layer, followed by vaporization, a photolithography method, or the like.

The method for vaporizing a part of the coating layer may be performed using devices generally known in the art, for example, a UV laser device having a central wavelength of about 300 nm to about 400 nm, an IR laser device having a central wavelength of about 1,000 nm to about 1,100 nm, a green laser device having a central wavelength of about 500 nm to about 550 nm, or the like. Meanwhile, laser processing conditions such as the kind, laser power, and a pulse repetition ratio of the laser device may be changed according to the kind and a thickness of the coating layer, formation of the perforation part to be formed, and the like, and a person having ordinary skill in the art may appropriately select the laser processing conditions in consideration of the aforementioned matters.

According to an exemplary embodiment of the present specification, the step of forming the perforation part by selectively removing a partial area of the coating layer may be performed by laser processing.

Meanwhile, if the coating layer is formed of the photosensitive resin composition, the perforation part may be formed by a photolithography process. For example, the perforation part may be formed by a method for applying the photosensitive resin composition on the other surface of the polarizing plate and selectively exposing the energy beam to an area corresponding to the perforation part and then developing the area with a developing solution.

In this case, the exposure may be performed using a light source such as a UV beam or an energy beam such as a laser. If the exposure is performed using the laser, there are merits in that a separate mask may not be used for exposure, and a shape of the perforation part may be relatively freely formed.

More specifically, in an exemplary embodiment of the present specification, if the coating layer is formed of the photosensitive resin composition to a thickness of 200 nm, the exposure may be performed using a core having the maximum average power of about 0.1 W to about 10 W and a UV laser of 300 nm to 400 nm. In this case, an action pulse repetition rate of the laser may be about 30 kHz to about 100 kHz.

Meanwhile, in the developing, an appropriate developing solution may be selected to be used according to the kind of the photosensitive resin used herein. In some cases, the above-described bleaching solution may be used as the developing solution. In this case, a separate developing step may not be performed.

Meanwhile, the perforation part may be formed to correspond to a shape of an area to be bleached, and a shape or a formation position thereof is not particularly limited. For example, the perforation part may be formed at a position at which components such as a camera are mounted, so as to correspond to a shape of the components, or may be formed in an area in which a product logo is printed in a shape of the product logo. If a color is provided to an edge portion of the polarizer, the perforation part may be formed at the edge portion of the polarizer to have a frame shape.

According to an exemplary embodiment of the present specification, the method may further include a step of providing a release film on an opposite surface of the protective film facing the polarizer before the step of forming the depolarized area.

If the bleaching process is performed after the release film is further provided, it is possible to minimize a sagging phenomenon caused by MD shrinkage occurring when the polarizer is swollen.

According to an exemplary embodiment of the present specification, the release film may have a force of 6,000 N or more. The force means a value obtained by the following Equation 1.

Force(N)=Modulus (N/mm²)×Thickness of film (mm)×Width of film (mm) [Equation 1]

In the present specification, the modulus (Young's modulus) refers to a value obtained by fixing both ends of a sample prepared according to the JIS-K6251-1 standard and then applying a force in a direction perpendicular to a thickness direction of the film, to measure stress per unit area according to strain. In this case, as an measurement apparatus, for example, a tensile strength tester (Zwick/Roell Z010 U™) and the like may be used.

A force of the release film may be adjusted by changing the thickness of the release film. The degree of change in force according to the thickness of the release film may be changed depending on a material of the release film. However, a method for adjusting the force of the release film is not limited thereto.

Then, a step of forming a depolarized area having a single transmittance of 80% or more in a wavelength band of 400 nm to 800 nm by bringing a bleaching solution including 1 wt % to 30 wt % of a bleaching agent into local contact with the other surface of the polarizer on which the protective film is provided as described above is performed. In this case, a surface tension of the bleaching solution is 50 mN/m or less.

In order to reduce the surface tension of the bleaching solution and more specifically, in order to reduce the surface tension to 50 mN/m or less, a method of adding an alcohol-based solvent such as methanol, ethanol, and isopropyl alcohol in an amount of 1 wt % to 50 wt % with respect to the total weight of the bleaching solution and/or a method of adding a small amount of a surfactant may be used.

The kind of the surfactant is not particularly limited. That is, the surfactant may be a cation-based surfactant, an anion-based surfactant, an amphoteric surfactant, or a non-ionic surfactant.

According to an exemplary embodiment of the present specification, the bleaching solution may further include a surfactant. Specifically, the surfactant may be added in an amount of 0.01 wt % to 0.5 wt % with respect to the total weight of the bleaching solution.

In this case, the other surface of the polarizer refers to an opposite surface where the protective film and/or the release film are not provided, as described above. That is, since the bleaching solution needs to come into direct contact with the polyvinyl alcohol-based polarizer instead of the protective film and/or the release film, the present step should be performed to the other surface of the polarizer.

The method of providing the mask layer and then performing the bleaching process (process of forming the depolarized area) has an advantage of high ease of performing consecutive processes, but has a problem in that the bleaching solution cannot fully fill the perforation part due to an end of the mask layer and a micro bubble is generated at a boundary, which causes generation of an unbleached site. The generation of the unbleached site means formation of a bleached site into an undesired shape.

The end of the mask layer refers to a height corresponding to a thickness of the mask layer.

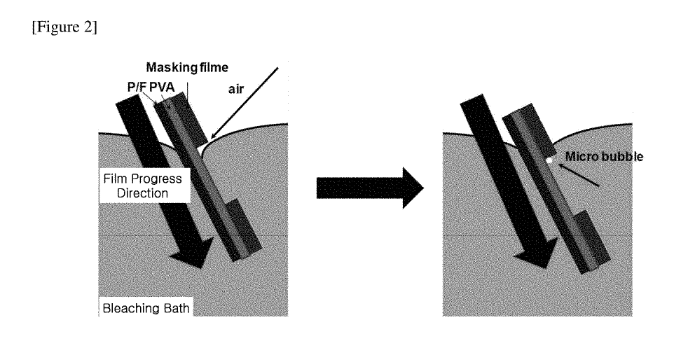

Referring to FIG. 2, the cause of formation of a micro bubble which causes generation of an unbleached site is permeation of air through the end at the boundary of the mask layer. This is because a contact angle between the mask layer and the bleaching solution is high due to a high surface tension of the bleaching solution.

Accordingly, the method for manufacturing a polarizing plate according to an exemplary embodiment of the present specification suppresses generation of an unbleached site using a bleaching solution having a low surface tension.

According to an exemplary embodiment of the present specification, a surface tension of the bleaching solution may be 30 mN/m or less. In this case, the above-described effect of suppressing an unbleached site can be maximized That is, a defect rate can be minimized

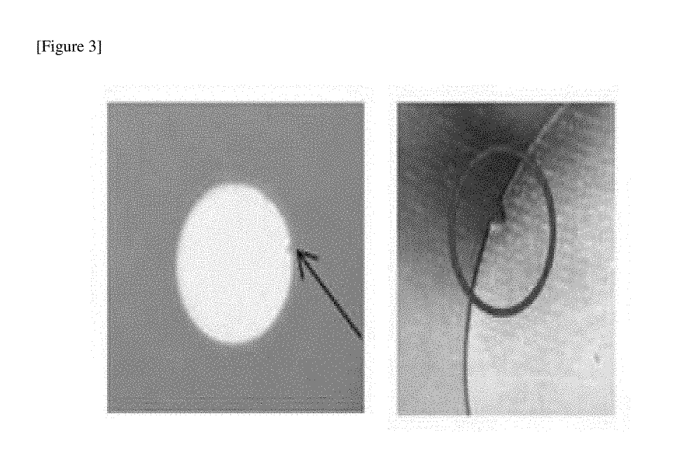

FIG. 3 is a diagram illustrating an unbleached site caused by a micro bubble. It can be seen that complete bleaching cannot be achieved but an unbleached site in the form of a small drop is generated.

According to an exemplary embodiment of the present specification, a contact angle between the bleaching solution and the polarizer may be 30 degrees or less. If the contact angle is 30 degrees or less, permeation of air can be minimized, so that generation of an unbleached site caused by a micro bubble can be suppressed.

According to an exemplary embodiment of the present specification, the contact angle between the bleaching solution and the polarizer may be 20 degrees or less and more preferably 10 degrees or less. In this case, the above-described effect of minimizing permeation of air and thus suppressing generation of an unbleached site can be maximized.

According to an exemplary embodiment of the present specification, the depolarized area may be formed at a ratio of 0.005% to 40% with respect to the entire polarizing plate.

Meanwhile, the bleaching solution essentially includes a bleaching agent which may bleach the iodine and/or dichroic dye, and a solvent. The bleaching agent is not particularly limited as long as the bleaching agent may bleach the iodine and/or dichroic dye dyed on the polarizer. According to an exemplary embodiment of the present specification, the bleaching agent may include one or more kinds of bleaching agents selected from the group consisting of sodium hydroxide (NaOH), sodium hydrosulfide (NaSH), sodium azide (NaN₃), potassium hydroxide (KOH), potassium hydrosulfide (KSH), and potassium thiosulfate (KS₂O₃).

As the solvent, water such as distilled water may be preferably used. Further, the solvent may be used as being additionally mixed with an alcohol-based solvent. The solvent may be used as being mixed with, for example, but not limited to, methanol, ethanol, butanol, isopropyl alcohol, or the like. As described above, the alcohol-based solvent may be added in an amount of 1 wt % to 50 wt % with respect to the total weight of the bleaching solution to lower a surface tension of the bleaching solution. More specifically, the surface tension of the bleaching solution can be reduced to 50 mN/m or less. In the above-described range, as the content of the alcohol-based solvent is increased, the surface tension of the bleaching solution is decreased.

Meanwhile, the content of the bleaching agent in the bleaching solution may be changed according to a contact time in the bleaching process, but the bleaching agent may be included in an amount of preferably about 1 wt % to about 30 wt % and more preferably about 5 wt % to about 15 wt %, with respect to the total weight of the bleaching solution. If the content of the bleaching agent is less than 1 wt %, bleaching may not be performed or bleaching may take several tens of minutes or more, and thus it is difficult to substantially apply the bleaching agent. If the content thereof is more than 30 wt %, the bleaching solution is not easily diffused into the polarizer, so that an increment in bleaching efficiency is insignificant and thus economic feasibility is reduced.

Further, according to an exemplary embodiment of the present specification, a pH of the bleaching solution may be 11 to 14. Preferably, the pH may be 13 to 14. The bleaching agent is a strong basic compound and should have a strong basic property sufficient to break boric acid forming a crosslinking bond with polyvinyl alcohol. If the pH satisfies the above-described range, bleaching may be performed well. For example, sodium thiosulfate (pH 7) as a solution decomposing (bleaching) iodine to secure transparency (iodine clock reaction) may cause bleaching in a general iodine compound aqueous solution but does not cause bleaching in an actual polarizer (PVA) even though contact is performed over a long period of time (10 hours). That is, this means that the crosslinking bond of the boric acid needs to be broken by the strong base before iodine is decomposed.

According to an exemplary embodiment of the present specification, a viscosity of the bleaching solution may be 1 cP to 2,000 cP. More specifically, according to an exemplary embodiment of the present specification, the viscosity of the bleaching solution may be 5 cP to 2,000 cP. This is because if the viscosity of the bleaching solution satisfies the above-described numerical range, a printing process may be readily performed and diffusion or flowing down into the printed bleaching solution according to movement of the polarizing member in a continuous process line may be suppressed and thus a bleached area may be formed into a desired shape in a desired area. Meanwhile, the viscosity of the bleaching solution may be appropriately changed according to surface properties of the printing device and the polarizer used herein. For example, in case of using the gravure printing method, the viscosity of the bleaching solution may be about 1 cP to about 2,000 cP and preferably about 5 cP to about 200 cP, and in case using the inkjet printing method, the viscosity of the bleaching solution may be about 1 cP to about 55 cP and preferably about 5 cP to about 20 cP.

Meanwhile, preferably, the step of forming the depolarized area may be performed in the bleaching solution at 10° C. to 70° C. for 1 second to 60 seconds. If the temperature and the immersion time of the bleaching solution is out of the above-described numerical range, there may be problems in that swelling and syneresis of the polarizer are caused by the bleaching solution, so that bending of the polarizer occurs or bleaching occurs even in an undesired area.

According to an exemplary embodiment of the present specification, the bleaching solution may further include a viscosity agent. In order for the viscosity of the bleaching solution to satisfy the above-described range, it is preferable to use a method of further adding the viscosity agent. Therefore, the viscosity agent improves the viscosity of the bleaching solution to help to suppress diffusion of the solution and form the depolarized area having a desired size at a desired position. If the solution having a high viscosity is applied on the rapidly moving polarizer, since a relative speed difference between a liquid and the polarizer, which is generated during the application, is reduced, diffusion of the solution into an undesired portion is suppressed, and the flow of the solution, which is applied for a time when bleaching is performed until washing after application, is reduced, and thus a depolarized area having a desired position or size may be formed.

The viscosity agent is not particularly limited as long as the viscosity agent has low reactivity and may increase the viscosity of the solution. According to an exemplary embodiment of the present specification, the viscosity agent includes one or more kinds of viscosity agents selected from the group consisting of a polyvinyl alcohol-based resin, a polyvinyl acetoacetate-based resin, an acetoacetyl group-denatured polyvinyl alcohol-based resin, a butenediolvinyl alcohol-based resin, a polyethylene glycol-based resin, and a polyacrylamide-based resin.

According to another exemplary embodiment, the viscosity agent may be included in a content of 0.5 wt % to 30 wt % with respect to the total weight of the bleaching solution. Specifically, according to an exemplary embodiment of the present specification, the viscosity agent may be included in a content of 2.5 wt % to 15 wt % with respect to the total weight of the bleaching solution. If the content of the viscosity agent is more than the above-described range, the viscosity is excessively increased, and, thus, washing is not effectively performed. If the content of the viscosity agent is excessively low, the viscosity is low, and, thus, it is difficult to implement a bleached area having a desired shape and a desired size by diffusion and flow of the liquid.

According to an exemplary embodiment of the present specification, the bleaching solution may include: 1 wt % to 30 wt % of the bleaching agent; 0.5 wt % to 30 wt % of the viscosity agent; and 40 wt % to 70 wt % of water, with respect to the total weight.

Further, the depolarized area may have various shapes but is not limited thereto, and the depolarized area may be formed at any position on the entire polarizing plate. However, for example, if the depolarized area is formed on a camera module, the depolarized area may have a size of preferably about 0.01 cm² to about 5 cm².

Meanwhile, a depolarization mechanism through the depolarization step of the present specification will be specifically described below. It is known that a polyvinyl alcohol complex dyed with the iodine and/or dichroic dye may absorb a light in a range of visible rays, such as a wavelength band of 400 nm to 800 nm. In this case, if the bleaching solution is brought into contact with the polarizer, the iodine and/or dichroic dye absorbing a light having the visible-ray wavelength band and existing in the polarizer are decomposed to bleach the polarizer and thus increase a transmittance and reduce a polarization degree. For example, the depolarized area may have a single transmittance of 80% or more and a polarization degree of 20% or less in a wavelength band of 400 nm to 800 nm.

In the present specification, the term “single transmittance” is represented by an average value of transmittance of an absorption axis and transmittance of a transmission axis of the polarizing plate. Further, the term “single transmittance” and the term “polarization degree” of the present specification are values measured using the V-7100 model manufactured by JASCO company.

For example, if an aqueous solution including potassium hydroxide (KOH), which is the bleaching agent, is brought into contact with a partial area of the polyvinyl alcohol-based polarizer dyed with iodine, iodine is decomposed by a series of processes as indicated by the following Chemical Formulas 1 and 2. Meanwhile, if a boric acid crosslinking process is performed when the polyvinyl alcohol-based polarizer dyed with iodine is manufactured, potassium hydroxide directly decomposes the boric acid to remove a crosslinking effect caused by hydrogen bonding of polyvinyl alcohol and the boric acid as described in the following Chemical Formula 3.

12KOH+6I₂→2KIO₃+10KI+6H₂O [Chemical Formula 1]

I₅⁻+IO₃⁻+6H⁺→3I₂+3H₂O

I₃⁻→I⁻+I₂ [Chemical Formula 2]

B(OH)₃+3KOH→K₃BO₃+3H₂O [Chemical Formula 3]

That is, the polarizer absorbs a light in the visible-ray region to decompose iodine and/or iodine ion complexes such as I₅⁻ (620 nm), I₃⁻ (340 nm), and I₂⁻ (460 nm) and thus generate I⁻ (300 nm or less) or a salt thereof, thereby transmitting most of the light in the visible-ray region. Accordingly, since the polarizer is depolarized in the region of about 400 nm to 800 nm, which is the visible-ray region, the transmittance is entirely increased to make the polarizer transparent. In other words, in order to make polarization in the polarizer, arranged iodine complexes absorbing the visible rays may be decomposed into monomers which do not absorb the visible rays, thereby performing depolarization.

According to an exemplary embodiment of the present specification, the method may further include, if necessary, a step of removing a mask layer after the step of forming the depolarized area. The step of removing the mask layer may be performed by a method of stripping the mask layer from the polarizer. If the mask film is used as the mask layer, it is preferable to perform the present step, but if the coating layer is used as the mask layer, the present step may not be performed. More specifically, the step of removing the mask layer may be performed by a method of stripping the mask layer from the polarizer using a stripping roll and the like.

According to an exemplary embodiment of the present specification, the method may further include, if necessary, a step (not illustrated) of crosslinking the polarizer after the step of forming the depolarized area. In the step of forming the depolarized area through a contact with the bleaching solution, the bleached area may be swollen due to the bleaching solution, so that the polarizer may be deformed. Thus, the crosslinking step is performed to restore the deformed polarizer and may be performed by a method of immersing the polarizer in a crosslinking solution.

Herein, the crosslinking solution may include one or more kinds of crosslinking agents selected from the group consisting of boron compounds such as a boric acid and borax; and acids such as succinic acid, glutaric acid, and citric acid.

The content of the crosslinking agent may vary depending on the kind of the crosslinking agent, and may be, for example, about 0.001 wt % to about 20 wt %, preferably about 0.003 wt % to about 15 wt %, and more preferably about 0.005 wt % to about 10 wt %. If a boron compound is used as the crosslinking agent, the content of the crosslinking agent may be about 0.001 wt % to about 5 wt %, and if an acid is used as the crosslinking agent, the content of the crosslinking agent may be about 0.001 wt % to about 1 wt %. If the content of the crosslinking agent satisfies the above-described numerical range, excellent process yield and appearance quality, optical properties and/or durability of the polarizing plate can be achieved. Meanwhile, water (pure water) may be used as a solvent of the crosslinking solution.

According to an exemplary embodiment of the present specification, in order to adjust properties and a color of the polarizing plate, the crosslinking solution may further include an iodide compound such as potassium iodide, lithium iodide, sodium iodide, zinc iodide, aluminum iodide, lead iodide, copper iodide, barium iodide, calcium iodide, tin iodide, titanium iodide, or a mixture thereof. In this case, the content of the iodide compound may be preferably about 3 wt % to about 5 wt %. If the content of the iodide compound is out of the above-described numerical range, the durability or color properties of the polarizer may be adversely affected.

Meanwhile, a temperature of the crosslinking solution during the crosslinking process may be, for example, but not limited to, about 10° C. to about 70° C., preferably about 15° C. to about 65° C., and more preferably about 20° C. to about 60° C. If the temperature of the crosslinking solution satisfies the above-described numerical range, deformation of the polarizing member caused by the bleaching process can be effectively corrected. If the temperature of the crosslinking solution is out of the above-described numerical range, the optical properties or appearance quality of the polarizing member may deteriorate, and in severe cases, the deformation of the polarizing member may worsen.

Further, a time of performing the crosslinking process may be, for example, but not limited to, about 1 second to about 120 seconds, preferably about 1 second to about 90 seconds, and more preferably about 1 second to about 60 seconds. If the crosslinking time satisfies the above-described numerical range, deformation of the polarizing member caused by bleaching can be effectively corrected. If the crosslinking time is out of the above-described numerical range, the optical properties or quality of the polarizing member may deteriorate, and in severe cases, the deformation of the polarizing member may worsen.

As described above, if the polarizing member is immersed in the crosslinking solution including the crosslinking agent, polyvinyl alcohol chains in the PVA film are bonded to each other by the boron compound or acid included in the crosslinking solution, so that an effect of correcting the deformation of the polarizing member can be achieved. According to the research of the inventors of the present invention, if the crosslinking process is performed after the step of forming the depolarized area, a dimension deformation rate of the bleached area is reduced to 10% to 70% and generally about 20% to about 60%, as compared with a case where the crosslinking process is not performed.

According to an exemplary embodiment of the present specification, the method may further include a step of cleaning and drying the polarizer after the step of forming the depolarized area. More specifically, if the crosslinking step is included, the cleaning and drying step may be additionally performed after the crosslinking step.

The cleaning and drying step is performed to wash the crosslinking solution remaining on the polarizer and further correct appearance deformation of the polarizing member caused by the bleaching solution, and may be performed by a method of cleaning and drying a polarizer as known in the art.

According to an exemplary embodiment of the present specification, the cleaning and drying step may be performed by allowing the polarizer to pass through a cleaning roll and a heating roll. In this case, the heating roll may have a diameter of about 100Φ to about 500Φ and preferably about 150Φ to about 300Φ. A temperature of the heating roll may be about 30° C. to about 150° C. and preferably about 60° C. to about 150° C. According to the research of the inventors of the present invention, the effect of correcting the appearance deformation of the polarizing member varies depending on a diameter and a temperature of the heating roll in the cleaning and drying step, and if a diameter and a temperature of the heating roll satisfies the above-described numerical range, the appearance deformation of the polarizing member can be corrected most effectively.

According to an exemplary embodiment of the present specification, in order to further improve a surface roughness of the polarizer, the method may further include a step of forming a flattening layer on one surface of the polarizer after the crosslinking step. Preferably, the flattening layer may be formed on a surface in contact with the bleaching solution (i.e., a surface on which the mask layer is formed) and may have a thickness of about 1 μm to about 10 μm and more preferably about 2 μm to about 5 μm.

According to an exemplary embodiment of the present specification, the method may further include a step of forming an optical layer on at least one surface of the polarizer after the step of forming the depolarized area. In this case, the optical layer may be a polymer film layer such as a protective film or a retardation film, a functional film layer such as a luminance improvement film, or a functional layer such as a hard coating layer, an antireflection layer, and an adhesive layer.

More specifically, according to an exemplary embodiment of the present specification, the optical layer is formed on the other surface of the polarizer. In other words, the optical layer is formed on a surface of the polarizer, on which the protective film and/or the release film are not provided.

If the crosslinking step is included, the step of forming the optical layer may be preferably performed after the crosslinking step.

Meanwhile, the optical layer may be directly attached onto or formed on a surface of the polyvinyl alcohol-based polarizer, or may be attached onto the protective film or the other coating layer attached onto one surface of the polyvinyl alcohol-based polarizer.

The optical layer may be formed by different methods depending on the kind of the optical layer to be formed, and for example, the optical layer may be formed using methods for forming an optical layer well known in the art, and the method thereof is not particularly limited.

According to an exemplary embodiment of the present specification, the method may further include a step of removing the release film after the step of forming the depolarized area. The step of removing the release film may be performed by a method of stripping the release film from the protective film. More specifically, the step of removing the release film may be performed by a method of stripping the release film from the protective film using a stripping roll and the like.

Since the release film serves to suppress the occurrence of sagging (stretching in a direction of the protective film) in the step of forming the depolarized area, it is preferable to remove the release film after the depolarized area is formed.

Another exemplary embodiment of the present specification provides a polarizing plate manufactured by the method for manufacturing a polarizing plate according to the above-described exemplary embodiment.

In the polarizing plate, the depolarized area may have an arithmetic mean roughness Ra of 200 nm or less.

In the polarizing plate, the depolarized area may have a root mean square roughness Rq of 200 nm or less.

The arithmetic mean roughness Ra is a value regulated in JIS B0601-1994 and represents a value obtained by sampling a reference length from a roughness curve in a direction of a mean line thereof and summating absolute values of deviations of the sampled portion from the mean line to the measured curve, followed by averaging, and the root mean square roughness Rq is regulated in JIS B0601-2001. The arithmetic mean roughness Ra and the root mean square roughness Rq are measured using the optical profiler (Nanoview E1000, Nano System Inc.).

Generally, if a roughness of a polarizer surface is increased, a haze is increased by refraction and reflection of light. If a roughness of the depolarized area satisfies the above-described range, a haze is sufficiently low and vivid visibility may be secured.

Further, the polarizing plate may have a polarization degree of 10% or less.

In the polarizing plate, the depolarized area may have a haze of 3% or less.

A depth of sagging of the polarizing plate may be 10 μm or less. In the present specification, the sagging means a phenomenon of sagging in a direction of the protective film occurring when the polyvinyl alcohol (PVA)-based polarizer comes into contact with the bleaching solution. A shallow depth of sagging means the low degree of sagging phenomenon, and the shallow depth of sagging may minimize distortion of an appearance of the polarizing plate, and, thus, there is a merit in that the adhesive can be uniformly applied when the protective film and the like are laminated on the other surface. As a result, when the polarizing plate having a structure where the protective film is present on both surfaces of the polarizer is manufactured, the occurrence of defects can be reduced.

Further, the shallow depth of sagging has a merit in that the polarizing plate with an improved appearance can be provided.

The depth of sagging may be measured using a white light three-dimension measuring machine (optical profiler) or a laser microscope (CLSM, confocal laser scanning microscope).

The depolarized area may have a single transmittance of 80% or more, preferably 90% or more, and more preferably 92% or more in a wavelength band of 400 nm to 800 nm and more preferably 450 nm to 750 nm, which is the visible-ray region. Further, the depolarized area may have a polarization degree of 10% or less and more preferably 5% or less. When the depolarized area has a higher single transmittance and a lower polarization degree, the visibility is improved, so that the performance and image quality of a camera lens to be located in the depolarized area can be further improved.

According to an exemplary embodiment of the present specification, the other area of the polarizing plate except the depolarized area may have a single transmittance of preferably 40% to 47% and more preferably 42% to 47%. Further, the other area of the polarizing plate except the depolarized area may have a polarization degree of preferably 99% or more. This is because the other area of the polarizing plate except the depolarized area needs to exhibit the excellent optical properties in the above-described range by functioning as a polarizing plate.

In the polarizing plate according to an exemplary embodiment of the present specification, a width of a boundary between the depolarized area and the polarized area may be 5 μm or more to 200 μm or less, or 5 μm or more to 100 μm or less, or 5 μm or more to 50 μm or less.

The boundary between the depolarized area and the polarized area may refer to an area of the polarizer located between the depolarized area and the polarized area. The boundary between the depolarized area and the polarized area may refer to an area in contact with each of the depolarized area and the polarized area. Further, the boundary between the depolarized area and the polarized area may refer to an area having a value between the single transmittance of the depolarized area and the single transmittance of the polarized area.

The width of the boundary between the depolarized area and the polarized area may refer to a shortest distance from an area having a value of the single transmittance of the depolarized area to an area having a value of the single transmittance of the polarized area. A smaller width of the boundary between the depolarized area and the polarized area may mean that the depolarized area is efficiently formed at a desired local site.

In the present specification, the polarized area may refer to an area of the polarizer except the depolarized area.

An exemplary embodiment of the present specification may also provide an image display device including: a display panel; and the polarizing plate attached to one surface or both surfaces of the display panel according to the above-described exemplary embodiment.

The display panel may be a liquid crystal panel, a plasma panel and an organic light-emitting panel. Thus, the image display device may be a liquid crystal display (LCD), a plasma display panel (PDP), and an organic light emitting diode (OLED).

More specifically, the image display device may be a liquid crystal display including: a liquid crystal panel; and polarizing plates provided on both sides of the liquid crystal panel, respectively. In this case, at least one of the polarizing plates may be the polarizing plate including the polarizer according to an exemplary embodiment of the present specification.

Herein, the kind of a liquid crystal panel included in the liquid crystal display is not particularly limited. Examples of the liquid crystal panel may include, but are not limited to, all known panels, including: passive matrix panels such as twisted nematic (TN) panels, super twisted nematic (STN) panels, ferroelectric (F) panels, or polymer dispersed (PD) panels; active matrix panels such as two-terminal type panels or three-terminal type panels; in-plane switching (IPS) panels; and vertical alignment (VA) panels, and the like. In addition, the kinds of other components of the liquid crystal display, for example, upper and lower substrates (for example, a color filter substrate or an array substrate), are not particularly limited, and those known in the art may be used without limitation.

According to an exemplary embodiment of the present specification, the image display device may further include a camera module provided in the depolarized area of the polarizing plate. An effect of increasing visibility of a camera lens portion may be secured by positioning the camera module in the depolarized area where the transmittance of a visible ray region is improved and the polarization degree is reduced. Further, if the step of forming the depolarized area is performed after the release film is provided, an appearance improvement effect may be secured by including the polarizing plate that suppresses a sagging phenomenon of the depolarized area.

An exemplary embodiment of the present specification also provides a bleaching solution having a surface tension of 50 mN/m or less. Specifically, the bleaching solution may be used in the step of forming the depolarized area of the polarizer while the polarizing plate is manufactured.

According to an exemplary embodiment of the present specification, the bleaching solution may include an alcohol-based solvent in an amount of 1 wt % to 50 wt % with respect to the total weight of the bleaching solution.

According to an exemplary embodiment of the present specification, the bleaching solution may include a surfactant in an amount of 0.01 wt % to 0.5 wt % with respect to the total weight of the bleaching solution.

If the content of the alcohol-based solvent and/or the surfactant is in the above-described range, a bleaching solution having a surface tension of 50 mN/m or less can be obtained.

The details of the alcohol-based solvent and the surfactant are the same as described above.

### [Mode]

Hereinafter, the present specification will be described in more detail with reference to examples. However, the following examples are set forth to illustrate the present specification, but the scope of the present specification is not limited thereto.

### Preparation Example

A polyvinyl alcohol-based film (Nippon Gohsei Co., Ltd. M3000 grade 30 μm) was subjected to a swelling process in a pure solution at 25° C. for 15 seconds, and then subjected to a dyeing process in an iodine solution having a concentration of 0.2 wt % at 25° C. for 60 seconds. Thereafter, the polyvinyl alcohol-based film was subjected to a cleaning process in a solution including 1 wt % of boric acid at 45° C. for 30 seconds and then 6-fold stretched in a solution including 2.5 wt % of boric acid at 52° C. After the stretching, the polyvinyl alcohol-based film was subjected to a complementary color process in a solution including 5 wt % of potassium iodide (KI), and then dried in an oven at 60° C. for 5 seconds, thereby manufacturing the polyvinyl alcohol-based polarizer having a thickness of 12 μm. Then, an acryl-based protective film was laminated on one surface of the polyvinyl alcohol-based polarizer and a masking film including a hole having a diameter of about 4 mm was laminated on the other surface of the polarizer. Then, polyethylene terephthalate (PET) was laminated on the other surface of the acryl-based protective film (an opposite surface of the protective film facing the polarizer) using an adhesive agent.

### Example 1

The polarizer on which the masking film including the hole was laminated on one surface and the protective film and polyethylene terephthalate (PET) were laminated on the other surface was immersed and bleached in a 60 KOH 10 wt % aqueous solution added with 0.2 wt % of a surfactant (BYK-348, BYK Chemie) for 3 seconds and then immersed and neutralized in a boric acid 4 wt % aqueous solution for 5 seconds and dried in an oven at 60° C. for 30 seconds. Then, the masking film was removed and an acryl-based protective film was laminated. Then, the polyethylene terephthalate (PET) film was removed, so that a polarizing plate having a structure including the acryl-based protective film/the polyvinyl alcohol-based polarized the acryl-based protective film was manufactured.

### Example 2

A polarizing plate was manufactured under the same conditions as Example 1 except that a bleaching solution added with 0.1 wt % of the surfactant (BYK-348, BYK Chemie) was used.

### Example 3

A polarizing plate was manufactured under the same conditions as Example 1 except that a bleaching solution added with 20 wt % of isopropyl alcohol was used.

### Example 4

A polarizing plate was manufactured under the same conditions as Example 1 except that a bleaching solution added with 10 wt % of isopropyl alcohol was used.

### Example 5

A polarizing plate was manufactured under the same conditions as Example 1 except that a bleaching solution added with 5 wt % of isopropyl alcohol was used.

### Comparative Example 1

A polarizing plate was manufactured under the same conditions as Example 1 except that a bleaching solution added with 2 wt % of isopropyl alcohol was used.

### Comparative Example 2

A polarizing plate was manufactured under the same conditions as Example 1 except that a bleaching solution added with 1 wt % of isopropyl alcohol was used.

### Comparative Example 3

A polarizing plate was manufactured under the same conditions as Example 1 except that a bleaching solution without including additives was used.

The unbleached site generation rates, i.e., defect rates, in the polarizing plates manufactured according to Examples 1 to 5 and Comparative Examples 1 to 3 were compared, and the result thereof was as illustrated in Table 1.

TABLE 1

| | | Contact angle | |
|---|---|---|---|
| | Surface tension | of bleaching | |
| | of bleaching | solution with | Defect |
| | solution (mN/m) | polarizer (°) | rate (%) |
| Example 1 | 20 | <10 | 0 |
| Example 2 | 20.3 | <10 | 0 |
| Example 3 | 28.2 | <10 | 0 |
| Example 4 | 36.8 | 15 | 3 |
| Example 5 | 44.9 | 30 | 5 |
| Comparative | 54.2 | 42 | 15 |
| Example 1 | | | |
| Comparative | 56.7 | 45 | 20 |
| Example 2 | | | |
| Comparative | 70 | 55 | 40 |
| Example 3 | | | |

As listed in Table 1, it can be seen that a polarizing plate manufactured by the manufacturing method according to an exemplary embodiment of the present specification, i.e., a polarizing plate in which a depolarized area was formed using a bleaching solution having a low surface tension and/or a bleaching solution having a small contact angle with a polarizer was remarkably reduced in unbleached site generation rate (defect rate) as compared with a polarizing plate in which a depolarized area was formed using a bleaching solution having a high surface tension.

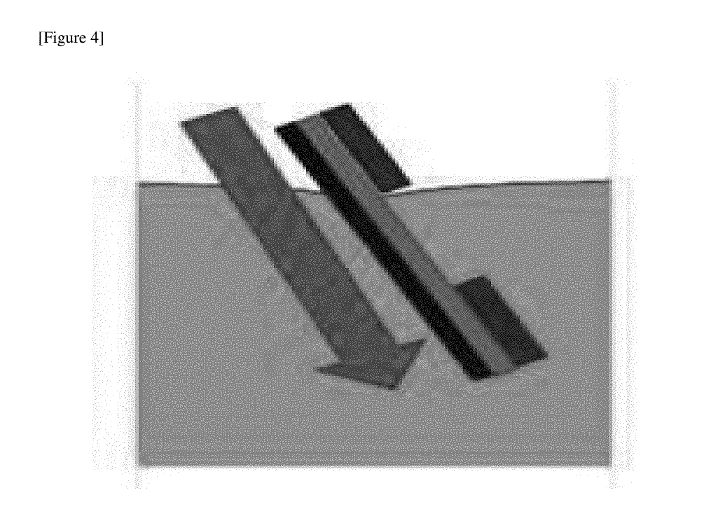

More specifically, referring to FIG. 4, if a surface tension of a bleaching solution is 30 mN/m or less, a contact angle between the bleaching solution and a polarizer is decreased. Thus, a micro bubble generation probability is decreased. Accordingly, an unbleached site generation rate (defect rate) is decreased as exhibited in Examples 1 to 5.

1. A method for manufacturing a polarizing plate, the method comprising:
providing a polyvinyl alcohol-based polarizer dyed with at least one of iodine and a dichroic dye;
providing a protective film on one surface of the polarizer;
providing a mask layer including at least one perforation part on the other surface of the polarizer; and
forming a depolarized area having a single transmittance of 80% or more in a wavelength band of 400 nm to 800 nm by bringing a bleaching solution including 1 wt % to 30 wt % of a bleaching agent into local contact with the other surface of the polarizer on which the mask layer is provided,
wherein a surface tension of the bleaching solution is 50 mN/m or less.

2. (canceled)

3. The method for manufacturing a polarizing plate of claim 1, wherein a contact angle between the bleaching solution and the polarizer is 30 degrees or less.

4. (canceled)

5. The method for manufacturing a polarizing plate of claim 1, wherein the bleaching solution further includes an alcohol-based solvent in an amount of 1 wt % to 50 wt % with respect to the total weight of the bleaching solution.

6. The method for manufacturing a polarizing plate of claim 1, wherein the bleaching solution further includes a surfactant in an amount of 0.01 wt % to 0.5 wt % with respect to the total weight of the bleaching solution.

7. The method for manufacturing a polarizing plate of claim 1, further comprising:
providing a release film on an opposite surface of the protective film facing the polarizer before the step of forming the depolarized area.

8. The method for manufacturing a polarizing plate of claim 7, further comprising:
removing the release film after the step of forming the depolarized area.

9.-14. (canceled)

15. The method for manufacturing a polarizing plate of claim 1, wherein the bleaching agent includes one or more kinds of bleaching agents selected from the group consisting of sodium hydroxide (NaOH), sodium hydrosulfide (NaSH), sodium azide (NaN3), potassium hydroxide (KOH), potassium hydrosulfide (KSH), and potassium thiosulfate (KS2O3).

16. The method for manufacturing a polarizing plate of claim 1, wherein a pH of the bleaching solution is 11 to 14.

17. The method for manufacturing a polarizing plate of claim 1, wherein a viscosity of the bleaching solution is 1 cP to 2,000 cP.

18. The method for manufacturing a polarizing plate of claim 1, wherein the bleaching solution further includes a viscosity agent.

19. (canceled)

20. The method for manufacturing a polarizing plate of claim 1, further comprising:
removing the mask layer after the step of forming the depolarized area.

21. The method for manufacturing a polarizing plate of claim 1, further comprising:
crosslinking the polarizer after the step of forming the depolarized area.

22. The method for manufacturing a polarizing plate of claim 1, further comprising:
cleaning and drying the polarizer after the step of forming the depolarized area.

23.-24. (canceled)

25. The method for manufacturing a polarizing plate of claim 1, further comprising:
forming an optical layer on at least one surface of the polarizer after the step of forming the depolarized area.

26. (canceled)

27. A polarizing plate manufactured according to claim 1.

28. An image display device, comprising:
a display panel; and
the polarizing plate of claim 27 attached to one surface or both surfaces of the display panel.

29. The image display device of claim 28, further comprising:
a camera module provided in the depolarized area of the polarizing plate.

30. A bleaching solution having a surface tension of 50 mN/m or less.

31. The bleaching solution of claim 30, wherein the bleaching solution includes an alcohol-based solvent in an amount of 1 wt % to 50 wt % with respect to the total weight of the bleaching solution.

32. The bleaching solution of claim 30, wherein the bleaching solution includes a surfactant in an amount of 0.01 wt % to 0.5 wt % with respect to the total weight of the bleaching solution.
